(19) United States
(12) Patent Application Publication
(10) Pub. No.: US 2002/0149979 A1
(43) Pub. Date: Oct. 17, 2002

(54) Method for identifying an integrated circuit and integrated circuit

(76) Inventors: Robert Kaiser, Kaufering (DE); Florian Schamberger, Bad Reichenhall (DE)

Correspondence Address: LERNER AND GREENBERG, P.A., PATENT ATTORNEYS AND ATTORNEYS AT LAW, Post Office Box 2480, Hollywood, CA, 33022-2480, US

(21) Appl. No.: 10/112,294

(22) Filed: Mar. 28, 2002

(30) Foreign Application Priority Data
Mar. 28, 2001 (DE) 101 15 293.0

(51) Int. Cl. G11C 7/00

(52) U.S. Cl. 365/200

(57) ABSTRACT

In order to identify an integrated circuit, the bits of the chip ID are programmed by fuses or antifuses. Programming errors and aging errors can be detected and corrected by adding redundant bits. This can be applied in particular when electrically programmable fuses/antifuses are used in order to make the re-detection of a faulty chip ID more reliable.

### BACKGROUND OF THE INVENTION

1. Field of the Invention:

The invention relates to a method for identifying an integrated circuit in which a digital identification word is provided in order to program programmable elements that are disposed on the integrated circuit.

Integrated circuits are provided with an individual identification in order to be identifiable. For example, semiconductor memories, in particular dynamic random access memories (DRAMs) are programmed with what is referred to as a chip ID so that the individual chip can be unambiguously identified during subsequent tests in the quality control system or in the application system when there are questions. The chip ID contains a multiplicity of bits in order to permanently provide information, for example, on the number of the manufacturing batch, the factory in which the chip was manufactured, electrical classifications and a serial number, on the integrated circuit itself. A chip ID can easily contain sixty or even more bits.

Programmable elements, also referred to as fuses or antifuses, are used to program the chip ID. The fuses and antifuses can be programmed by a laser pulse. Before the chip has been cast in the housing, the bits, which are intended to represent, for example, a logic “1” of the chip ID, are programmed with the laser and the other bits which are intended to represent a logic “0” are not programmed. A fuse has a low impedance or is conductive in the initial state and has high impedance or is not conductive in the programmed state. An antifuse is not conductive in the initial state and is conductive after the programming. The laser programming of the fuses and the antifuses can be carried out in a relatively reliable and stable fashion but has the disadvantage that a laser must be made available at a high cost and the programming can only be carried out before the encapsulation of the integrated circuit in a housing.

There have therefore been efforts to replace laser-programmable fuses and antifuses with electrically programmable fuses and antifuses. Such E-fuses and E-antifuses are programmed by electrical energy pulses, that is to say by impressing a sufficient current pulse given a correspondingly high programming voltage. The E-fuses and E-antifuses can also be programmed in chips that are already housed. The programming can be handled more flexibly by virtue of the completely electrical actuation of E-fuses/antifuses.

A disadvantage with the use of E-fuses/antifuses is however that an E-fuse still has a residual resistance after programming and an E-antifuse has only limited conductivity after programming. After programming E-fuses/antifuses a wide distribution of the conductivity values is therefore to be expected. Furthermore, it is disadvantageous that, owing to the aging of the semiconductor chip, the programmed conductivity changes in the course of time in the direction of the original initial state. The high impedance of a programmed E-fuse or the low impedance of a programmed E-antifuse decreases in the course of time. Therefore, there is the problem when electrically programmable fuses and antifuses are used for programming the chip ID that, on the one hand, the programming operation does not run with sufficient reliability and, on the other hand, the programming heals in the course of the operating time and its re-detection is consequently faulty.

### SUMMARY OF THE INVENTION

It is accordingly an object of the invention to provide a method for identifying an integrated circuit and an integrated circuit which overcome the above-mentioned disadvantages of the prior art methods and devices of this general type, in which the programming can be reliably read and re-detected.

With the foregoing and other objects in view there is provided, in accordance with the invention, a method for identifying an integrated circuit. The method includes the steps of providing a digital identification word containing a first number of bits, calculating an expanded identification word containing a second number of bits being larger than the first number of bits and has a fault-correcting redundancy for the digital identification word, and programming programmable elements disposed on the integrated circuit in dependence on the expanded identification word.

An integrated circuit which is particularly suitable for carrying out the method contains a configuration of programmable elements which are connected, on the one hand, to a terminal for a supply potential and, on the other hand, to a circuit node for reading out the conductivity state of the respective programmable element.

According to the invention, the original, uniquely defined chip ID is provided with redundant bits. The chip ID that is expanded with redundancy therefore has more bits than the original chip ID. The additional bits that are obtained by the redundancy can be added to the original chip ID at the edge or mixed with the original bits. By the additional redundancy it is possible to correct faultily programmed bits or bits of the chip ID that have become faulty owing to aging effects. Depending on the redundancy method used, the chip ID that is expanded with redundancy ensures the detection of a faulty chip ID per se and ensures the possibility of correcting one or more of the faulty bits. A precondition for this is that, during the reading-out operation, the redundancy-forming method is known and can be correspondingly decoded. In order to form redundancy and decode redundancy, a large number of methods in the technology are known per se. In principle, any redundancy-forming method can be applied.

The invention can be used particularly advantageously if elements that can be programmed electrically are used to program the bits of the chip ID. As explained at the beginning, with such E-fuses or E-antifuses, on the one hand, the programming operation becomes faulty and subject to tolerances and, on the other hand, healing effects during the course of the operation ensure that the programming automatically cancels itself out. When E-fuses/antifuses are used, the addition of redundancy to the chip ID has the particular advantage that these inherent disadvantages are compensated and corrected with relatively little expenditure.

One bit of the chip ID containing the redundancy is expediently assigned to a programmable element, that is to say a fuse or antifuse. In a first logic state, the fuse is preferably programmed by impressing a current and in the other logic state it is not programmed and retains the original state. In the case of a fuse, a programming device is provided that can change the conductivity from an originally low impedance to a high impedance. In the case of an antifuse, programming results in that the conductivity is changed from an originally high impedance to a low impedance.

For programming, the uniquely defined chip ID is made available in the automatic test equipment. The chip ID is fed to a redundancy algorithm that adds additional bits to the original chip ID in order to output a chip ID that has been expanded with redundancy. The chip ID is transmitted by the automatic test equipment to the integrated circuit. The electrical programming of the fuses/antifuses assigned to the bits of the chip ID takes place after this or together with the transmission of the expanded chip ID. To program the electrically programmable fuses/antifuses, a corresponding programming voltage is supplied which generates a sufficiently high current pulse inside the chip so that the desired change of the conductivity of the fuses/antifuses is brought about. To read out the chip ID it is necessary for the bits of the programmed chip ID to be read out and the redundant elements to be supplied within the scope of redundancy decoding for fault detection and fault correction in order to calculate the original uniquely defined chip ID.

The fuses/antifuses are connected, on the one hand, to a terminal for a supply potential, for example reference potential or ground, and, on the other hand, to a circuit node via which, on the one hand, the fuse is programmed and, on the other hand, the programmed state is read out. For reading out, the circuit node is preloaded and subsequently evaluated. A conductive fuse draws the node to the reference potential, and a non-conductive fuse leaves the node at the predefined potential. In this way, the programmed state of a logic “1” or logic “0” can be read out again. The circuit nodes are connected, for example to the inputs of a register that can be accessed from the outside for reading out.

As explained at the beginning, there is, in particular in the case of semiconductor memories, the requirement for a chip ID that can be reliably recognized again.

In accordance with an added mode of the invention, there is the step of forming the expanded identification word to contain all the bits of the digital identification word and further bits which are determined from the bits of the digital identification word by a redundancy calculation.

In accordance with another mode of the invention, there is the step of forming the programmable elements to initially have a high impedance and, if a respective bit has the first logic state, an associated one of the programmable elements assigned to the respective bit is changed to a low-impedance state by impressing an electric current pulse.

In accordance with a further mode of the invention, there is the step of forming the programmable elements to initially have a low impedance and, if a respective bit has the first logic state, an associated one of the programmable elements assigned to the respective bit is changed into a high impedance state by impressing an electrical current pulse.

Other features which are considered as characteristic for the invention are set forth in the appended claims.

Although the invention is illustrated and described herein as embodied in a method for identifying an integrated circuit and an integrated circuit, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 is a basic circuit diagram for a method sequence for programming an identification of an integrated circuit; and

FIG. 2 is a block diagram of a fuse bank that is disposed on an integrated circuit.

### DESCRIPTION OF THE PREFERRED EMBODIMENTS

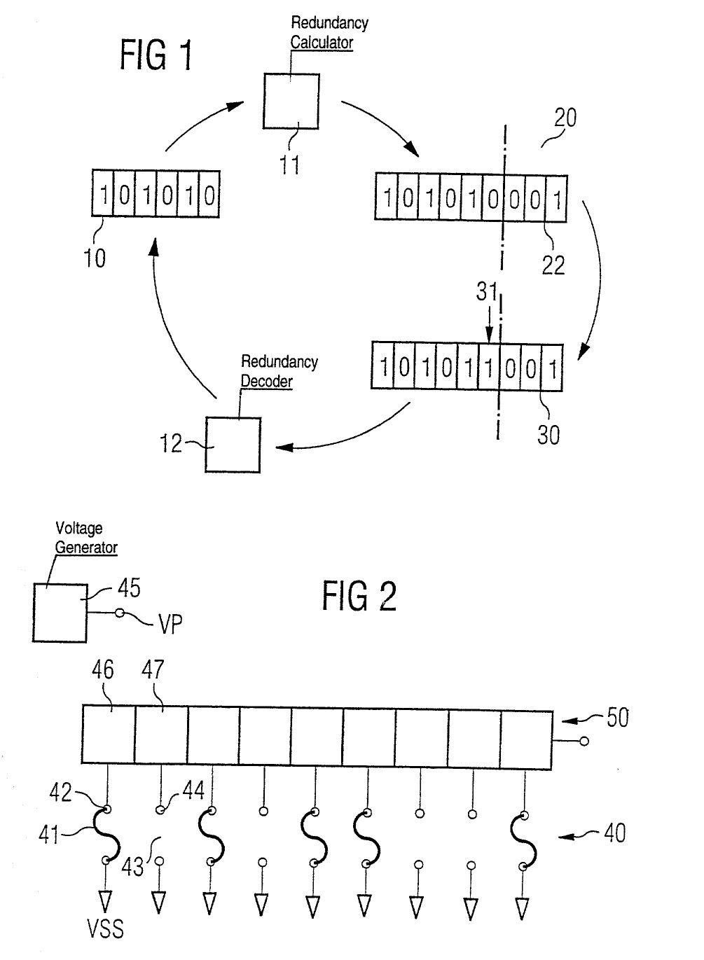

Referring now to the figures of the drawing in detail and first, particularly, to FIG. 1 thereof, there is shown a chip ID 10 which uniquely identifies an integrated circuit, in particular a DRAM. It contains six bits “101010”. For reasons of clarity, the chip ID 10 is kept short. In practice, it can contain up to sixty bits. Each of the bits of the chip ID 10 is assigned a fuse on the integrated semiconductor circuit. The assignment of one antifuse in each case is also conceivable. If a bit of the chip ID 10 is a logic “1”, the fuse is, for example, not programmed and retains the original, conductive state. If a bit of the chip ID 10 is a logic “0”, the fuse is electrically programmed with high impedance by a current pulse.

The chip ID 10 is subjected in the automatic test equipment to which the semiconductor memory is connected to a redundancy calculation 11 that generates a chip ID 20 that is expanded with redundancy. The chip ID 20 contains the original bits of the chip ID “101010” and a portion “001” that contains redundancy in accordance with the redundancy calculation 11. The automatic test equipment accordingly actuates the terminals of the semiconductor memory in such a way that the fuses provided for the chip ID are electrically programmed in accordance with the expanded chip ID 20.

The programming state of the fuse bank storing the chip ID 20 that comes about on the semiconductor chip after several years of service life is represented by a reference numeral 30. It is apparent that, instead of the original logic value “0”, the bit place 31 now has a logic “1”. It may either be the case that the programming of the E-fuse has already been carried out faultily or else the programming state has gradually changed from “0” to “1” owing to aging effects. When the chip ID 30 is read out, a redundancy decoding device 12, which evaluates the redundancy added in the redundancy calculation 11, is carried out. The redundant bits “001” permit the fault at the bit place 31 to be detected and even corrected in order to obtain the original chip ID 10 during reading out. Depending on the redundancy coding method 11 used and the number of redundant bits 22, it is possible either just to detect that there is a fault in the chip ID or else one or more faults can be corrected.

FIG. 2 shows a fuse bank 40 in which a programming state of the fuses is shown corresponding to the chip ID 30. A logic “1” of the chip ID 30 is represented by a conductive fuse, and the logic state “0” is represented by a fuse which is programmed with a high impedance. Each of the fuses, for example a fuse 41, is connected by one terminal to a reference potential VSS. Another terminal of the fuse 41 is connected to a circuit node 42. The fuse 41 is read out dynamically. For this purpose, the circuit node 42 is preloaded to a high potential. The conductive fuse 41 draws the potential to ground VSS. The potential is buffered at a bit place 46 of a register 50. The register 50 is embodied as a shift register so that all the bits of the stored chip ID 30 can be read out serially and fed to the decoding algorithm 12. At a bit place 47, the fuse 43 is programmed with a high impedance and constitutes a no-load operation at the terminal 44. When the terminal 44 is preloaded to the high potential, the potential is maintained and is stored as a logic “0” at the bit place of the shift register 50.

The fuse 43 was programmed electrically by impressing a correspondingly high current pulse during programming and the originally conductive fuse was subsequently destroyed and thus changed from the originally low-impedance state to the high-impedance state represented. The current pulse is generated by a voltage generator 45 that makes available a high programming voltage VP that is above the normal operating voltage.

We claim:

1. A method for identifying an integrated circuit, which comprises the steps of:
providing a digital identification word containing a first number of bits;
calculating an expanded identification word containing a second number of bits being larger than the first number of bits and has a fault-correcting redundancy for the digital identification word; and
programming programmable elements disposed on the integrated circuit in dependence on the expanded identification word.

2. The method according to claim 1, which comprises impressing a current during the step of programming the programmable elements in order to change a conductivity of at least one of the programmable elements.

3. The method according to claim 1, which comprises assigning each bit of the expanded identification word one of the programmable elements, and in that a conductivity of the bit is changed only if the bit has a first logic state of two possible logic states including a second logic state.

4. The method according to claim 1, which comprises forming the expanded identification word to contain all the bits of the digital identification word and further bits which are determined from the bits of the digital identification word by a redundancy calculation.

5. The method according to claim 3, which comprises forming the programmable elements to initially have a high impedance and, if a respective bit has the first logic state, an associated one of the programmable elements assigned to the respective bit is changed to a low-impedance state by impressing an electric current pulse.

6. The method according to claim 3, which comprises forming the programmable elements to initially have low impedance and, if a respective bit has the first logic state, an associated one of the programmable elements assigned to the respective bit is changed into a high impedance state by impressing an electrical current pulse.

7. An integrated circuit, comprising:
a supply terminal for a supply potential;
circuit nodes; and
a plurality of programmable elements connected between said supply terminal for the supply potential and said circuit nodes, said circuit nodes provided for reading out a conductivity state of said programmable elements.

8. The integrated circuit according to claim 7, further comprising a device for providing a programming current to change the conductivity state of said programmable elements irreversibly by feeding the programming current to one of said programmable elements in dependence on a state of an assigned bit of an expanded identification word, said device connected to said circuit nodes.
